(19) United States
(12) Patent Application Publication
(10) Pub. No.: US 2025/0372391 A1
(43) Pub. Date: Dec. 4, 2025

(54) PLANARIZING METHOD, PLANARIZING SYSTEM, AND METHOD OF MANUFACTURING AN ARTICLE

(71) Applicant: CANON KABUSHIKI KAISHA, Tokyo (JP)

(72) Inventors: Takahiro Nakayama, Austin, TX (US); Niyaz Khusnatdinov, Round Rock, TX (US); Timothy Brian Stachowiak, Austin, TX (US); Xing Yee Gan, Portland, OR (US); Craig William Cone, Austin, TX (US)

(21) Appl. No.: 18/679,188

(22) Filed: May 30, 2024

(51) Int. Cl. H01L 21/3105

(52) U.S. Cl. CPC H01L 21/31051

(57) ABSTRACT

A planarizing method comprises heating a superstrate held by a superstrate chuck by irradiating a photothermal coating layer on a surface of the superstrate, and heating and planarizing a formable material by contacting the heated superstrate with the formable material.

### BACKGROUND

### Field of Art

The present disclosure relates to substrate processing, and more particularly, to a superstrate used in the planarization of surfaces in semiconductor fabrication and methods of manufacturing an article using that superstrate.

### Description of the Related Art

Planarization and imprinting techniques are useful in fabricating semiconductor devices. For example, the process for creating a semiconductor device includes repeatedly adding and removing material to and from a substrate. This process can produce a layered substrate with an irregular height variation (i.e., topography), and as more layers are added, the substrate height variation can increase. The height variation has a negative impact on the ability to add further layers to the layered substrate. Separately, semiconductor substrates (e.g., silicon wafers) themselves are not always perfectly flat and may include an initial surface height variation (i.e., topography). One method of addressing this issue is to planarize the substrate between layering steps and/or before layering steps. Various lithographic patterning methods benefit from patterning on a planar surface. In ArFi laser-based lithography, planarization reduces the impact of depth of focus (DOF) limitations, and improves critical dimension (CD), and critical dimension uniformity. In extreme ultraviolet lithography (EUV), planarization improves feature placement and reduces the impact of DOF limitations. In nanoimprint lithography (NIL) planarization improves feature filling and CD control after pattern transfer.

A planarization technique sometimes referred to as inkjet-based adaptive planarization (IAP) involves dispensing a variable drop pattern of polymerizable material between the substrate and a superstrate, where the drop pattern varies depending on the substrate topography. A superstrate is then brought into contact with the polymerizable material after which the material is cured (polymerized) on the substrate, and the superstrate removed.

The curing is typically performed at room temperature, for example 20° C. The cured layer is then baked to form a baked layer. The thickness of the baked layer is thinner than the thickness of the photocurable composition. The thickness change reduces the planarization performance of the baked layer. The resulting surface of the baked layer may have a non-uniform topography that has some areas that are at a locally lower elevation and other areas that are at a locally higher elevation. A planarization layer having no elevational difference or at least less elevational differences across such surface is desired.

### SUMMARY

A planarizing method comprises heating a superstrate held by a superstrate chuck by irradiating a photothermal coating layer on a surface of the superstrate (plate), and heating and planarizing a formable material by contacting the heated superstrate with the formable material.

A planarization system comprises a superstrate, a superstrate chuck configured to hold the superstrate, a photothermal coating layer on a surface of the superstrate, and a light source configured to emit light to irradiate the photothermal coating layer such that the photothermal coating layer generates heat.

A method of manufacturing an article comprises dispensing a formable material on a substrate, heating the superstrate held by a superstrate chuck by irradiating a photothermal coating layer on a surface of the superstrate, heating and planarizing the formable material by contacting the heated superstrate with the formable material, curing the formable material, separating the superstrate from the cured formable material, baking the cured formable material at a baking temperature, wherein photothermal radiation parameters for irradiating the photothermal coating are determined based on the baking temperature, and processing the baked formable material to make the article.

These and other objects, features, and advantages of the present disclosure will become apparent upon reading the following detailed description of exemplary embodiments of the present disclosure, when taken in conjunction with the appended drawings, and provided claims.

### BRIEF DESCRIPTION OF DRAWINGS

So that features and advantages of the present disclosure can be understood in detail, a more particular description of embodiments of the disclosure may be had by reference to the embodiments illustrated in the appended drawings. It is to be noted, however, that the appended drawings only illustrate typical embodiments of the disclosure and are therefore not to be considered limiting of its scope, for the disclosure may admit to other equally effective embodiments.

FIG. 1 is a schematic diagram illustrating an example planarization system in accordance with an aspect of the present disclosure.

FIGS. 2A to 2C illustrate a schematic cross section of an example planarization process in accordance aspect of the present disclosure.

FIG. 3A shows a bottom view of an example superstrate chuck assembly in accordance with a first embodiment of the present disclosure.

FIG. 3B shows a top view of the superstrate chuck assembly of FIG. 3A.

FIG. 3C shows a cross section taken along line 3C-3C of FIG. 3B.

FIG. 3D shows an enlarged portion 3D of FIG. 3C.

FIG. 3E shows a perspective view of the enlarged portion 3D of FIG. 3C.

FIG. 4 shows an exploded view of the superstrate chuck assembly of FIGS. 3A to 3E.

FIG. 5 shows a schematic top view of a superstrate in accordance with an example embodiment.

FIG. 6A shows a schematic cross section view of the superstrate taken along line 6-6 of FIG. 5, in accordance with a first example embodiment.

FIG. 6B shows a schematic cross section view of the superstrate taken along line 6-6 of FIG. 5, in accordance with a second example embodiment.

FIG. 6C shows a schematic cross section view of the superstrate taken along line 6-6 of FIG. 5, in accordance with a third example embodiment.

FIG. 7 shows a flow chart of an example planarization method in accordance with aspect of the present disclosure.

FIGS. 8A to 8L show a series of schematic cross sections of the planarization method of FIG. 7, in accordance with an example embodiment.

FIGS. 9A to 9F, are temperature timing charts indicating the temperature of various components at different moments in the planarization method relative to an initial temperature at the start of the planarization method.

While the subject disclosure will now be described in detail with reference to the figures, it is done so in connection with the illustrative exemplary embodiments. It is intended that changes and modifications can be made to the described exemplary embodiments without departing from the true scope and spirit of the subject disclosure as defined by the appended claims.

### DETAILED DESCRIPTION

### Planarization System

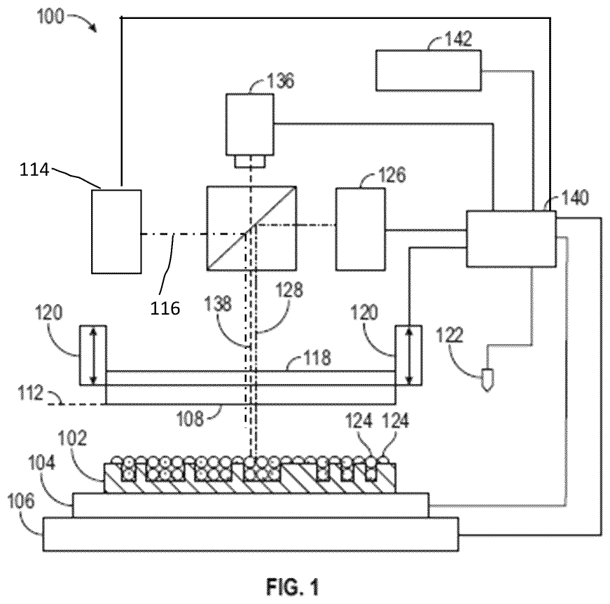

FIG. 1 illustrates an example system for shaping a surface in accordance with an aspect of the present disclosure. The system for shaping a surface may be, for example, a planarization system or an imprint system. The example embodiment described herein is a planarization system 100. However, the concepts are also applicable to an imprint system. Thus, while the terminology throughout this disclosure is primarily focused on planarization, it should be understood that the disclosure is also applicable to the corresponding terminology of an imprint context.

The planarization system 100 is used to planarize a film on a substrate 102. In the case of an imprint system, the imprint system is used to form a pattern on the film on the substrate. The substrate 102 may be coupled to a substrate chuck 104. The substrate chuck 104 may be but is not limited to a vacuum chuck, pin-type chuck, groove-type chuck, electrostatic chuck, electromagnetic chuck, and/or the like.

The substrate 102 and the substrate chuck 104 may be further supported by a substrate positioning stage 106. The substrate positioning stage 106 may provide translational and/or rotational motion along one or more of the x-, y-, z-, θ-, ψ, and φ-axes. The substrate positioning stage 106, the substrate 102, and the substrate chuck 104 may also be positioned on a base (not shown). The substrate positioning stage may be a part of a positioning system. The substrate positioning stage 106 may include a passive cooling system and/or an active cooling system.

Spaced apart from the substrate 102 is a superstrate 108 (also referred herein as a plate) having a working surface 112 facing substrate 102. The superstrate 108 may be formed from materials including, but not limited to, fused silica, quartz, silicon, organic polymers, siloxane polymers, borosilicate glass, fluorocarbon polymers, metal, hardened sapphire, and/or the like. In an embodiment the superstrate is readily transparent to UV light. The working surface 112 is generally of the same areal size or slightly smaller as the surface of the superstrate 108. One more photothermal coating layers may be provided on one or more surfaces of the superstrate 108 as part of a heating system, which is describe below.

The superstrate 108 may be coupled to or retained by a superstrate chuck assembly 118 (also referred herein as a superstrate chuck assembly), which is discussed in more detail below. The superstrate chuck assembly 118 may be coupled to a planarization head 120 which is a part of the positioning system. In the context of an imprint system, the planarization head may be referred to as an imprint head. The planarization head 120 may be movably coupled to a bridge. The planarization head 120 may include one or more actuators such as voice coil motors, piezoelectric motors, linear motor, nut and screw motor, etc., which are configured to move the superstrate chuck assembly 118 relative to the substrate 102 in at least the z-axis direction, and potentially other directions (e.g., x-, y-, θ-, ψ-, and φ-axis).

The planarization system 100 may further comprise a fluid dispenser 122. The fluid dispenser 122 may also be movably coupled to the bridge. In an embodiment, the fluid dispenser 122 and the planarization head 120 share one or more of all positioning components. In an alternative embodiment, the fluid dispenser 122 and the planarization head move independently from each other. The fluid dispenser 122 may be used to deposit droplets of liquid formable material 124 (e.g., a photocurable polymerizable material) onto the substrate 102 with the volume of deposited material varying over the area of the substrate 102 based on at least in part upon its topography profile. Different fluid dispensers 122 may use different technologies to dispense formable material 124. When the formable material 124 is jettable, ink jet type dispensers may be used to dispense the formable material. For example, thermal ink jetting, microelectromechanical systems (MEMS) based ink jetting, valve jet, and piezoelectric ink jetting are common techniques for dispensing jettable liquids.

The planarization system 100 may further comprise a heating system that includes a first radiation source 114 that directs light along an exposure path 116. The heating system also includes the one or more photothermal coating layers 166, 166a, 166b. The planarization head 120 and the substrate positioning stage 106 may be configured to position the superstrate 108 in superimposition with the exposure path 116. The first radiation source 114 sends the photothermal light (photothermal energy) along the exposure path 116 before the superstrate 108 has contacted the formable material 124, and causes the one or more photothermal coating layers to produce heat, as discussed in more detail below.

The planarization system 100 may further comprise a curing system that includes a second radiation source 126 that directs curing light (actinic energy), for example, UV radiation, along an exposure path 128. The planarization head 120 and the substrate positioning stage 106 may also be configured to position the superstrate 108 and the substrate 102 in superimposition with the exposure path 128. The second radiation source 126 sends the actinic energy along the exposure path 128 after the superstrate 108 has contacted the formable material 124. FIG. 1 shows the exposure path 128 when the superstrate 108 is not in contact with the formable material 124. This is done for illustrative purposes so that the relative position of the individual components can be easily identified. An individual skilled in the art would understand that exposure path 128 would not substantially change when the superstrate 108 is brought into contact with the formable material 124.

The planarization system 100 may further comprise a camera 136 positioned to view the spread of formable material 124 as the superstrate 108 contacts the formable material 124 during the planarization process. FIG. 1 illustrates an optical axis 138 of the field camera's imaging field. As illustrated in FIG. 1, the planarization system 100 may include one or more optical components (dichroic mirrors, beam combiners, prisms, lenses, mirrors, etc.) which combine the actinic radiation with light to be detected by the camera 136. The camera 136 may include one or more of a CCD, a sensor array, a line camera, and a photodetector which are configured to gather light at a wavelength that shows a contrast between regions underneath the superstrate 108 and in contact with the formable material 124 and regions underneath the superstrate 108 but not in contact with the formable material 124. The camera 136 may be configured to provide images of the spread of formable material 124 underneath the superstrate 108, and/or the separation of the superstrate 108 from the planarized layer 146. The camera 136 may also be configured to measure interference fringes, which change as the formable material 124 spreads between the gap between the working surface 112 and the substrate surface. The camera 136 may also be configured to measure interference fringes due to reflections from the working surface 112 and substrate surface.

The planarization system 100 may be regulated, controlled, and/or directed by one or more processors 140 (controller) in communication with one or more components and/or subsystems such as the substrate chuck 104, the substrate positioning stage 106, the superstrate chuck assembly 118, the planarization head 120, the fluid dispenser 122, the first radiation source 114, the second radiation source 126, and/or the camera 136. The processor 140 may operate based on instructions in a computer readable program stored in a non-transitory computer memory 142. The processor 140 may be or include one or more of a CPU, MPU, GPU, ASIC, FPGA, DSP, and a general-purpose computer. The processor 140 may be a purpose-built controller or may be a general-purpose computing device that is adapted to be a controller. Examples of a non-transitory computer readable memory include but are not limited to RAM, ROM, CD, DVD, Blu-Ray, hard drive, networked attached storage (NAS), an intranet connected non-transitory computer readable storage device, and an internet connected non-transitory computer readable storage device. All of the method steps described herein may be executed by the processor 140.

In operation, either the planarization head 120, the substrate positioning stage 106, or both vary a distance between the superstrate 108 and the substrate 102 to define a desired space (a bounded physical extent in three dimensions) that is filled with the formable material 124. For example, the planarization head 120 may be moved toward the substrate and apply a force to the superstrate 108 such that the superstrate contacts and spreads droplets of the formable material 124 as further detailed herein.

### Planarization Process

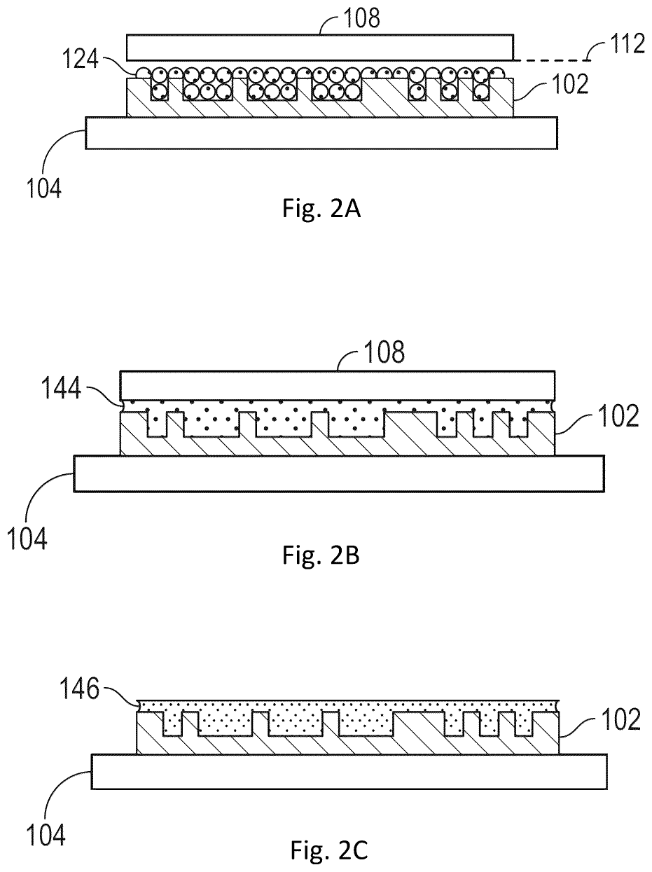

The planarization process includes steps which are shown schematically in FIGS. 2A-2C. As illustrated in FIG. 2A, the formable material 124 is dispensed in the form of droplets onto the substrate 102. As discussed previously, the substrate surface has some topography which may be known based on previous processing operations or may be measured using a profilometer, AFM, SEM, or an optical surface profiler based on optical interference effect like Zygo NewView 8200. The local volume density of the deposited formable material 124 is varied depending on the substrate topography. The superstrate 108 is then positioned in contact with the formable material 124.

FIG. 2B illustrates a post-contact step after the superstrate 108 has been brought into full contact with the formable material 124 but before a polymerization process starts. As the superstrate 108 contacts the formable material 124, the droplets merge to form a formable material film 144 that fills the space between the superstrate 108 and the substrate 102. Preferably, the filling process happens in a uniform manner without any air or gas bubbles being trapped between the superstrate 108 and the substrate 102 in order to minimize non-fill defects. The polymerization process or curing of the formable material 124 may be initiated with actinic radiation (e.g., UV radiation). For example, second radiation source 126 of actinic radiation of FIG. 1 can provide the actinic radiation causing formable material film 144 to cure, solidify, and/or cross-link, defining a cured planarized layer 146 on the substrate 102. Alternatively, curing of the formable material film 144 can also be initiated by using heat, pressure, chemical reaction, other types of radiation, or any combination of these. Once cured, a planarized layer 146 is formed, and the superstrate 108 can be separated therefrom. FIG. 2C illustrates the cured planarized layer 146 on the substrate 102 after separation of the superstrate 108. The substrate 102 and the planarized layer 146 may then be subjected to additional known steps and processes for device (article) fabrication, including, for example, baking, patterning, curing, oxidation, layer formation, deposition, doping, planarization, etching, formable material removal, dicing, bonding, and packaging, and the like. The substrate may be processed to produce a plurality of articles (devices).

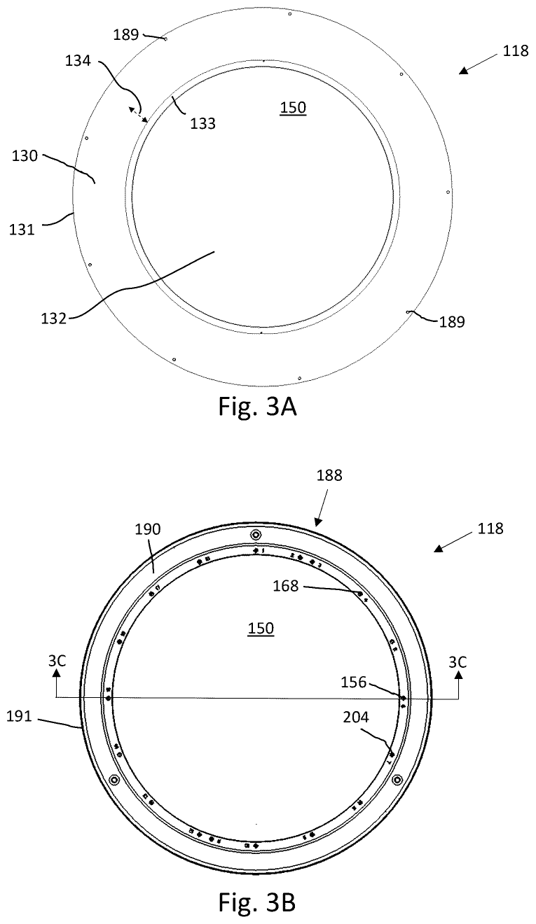

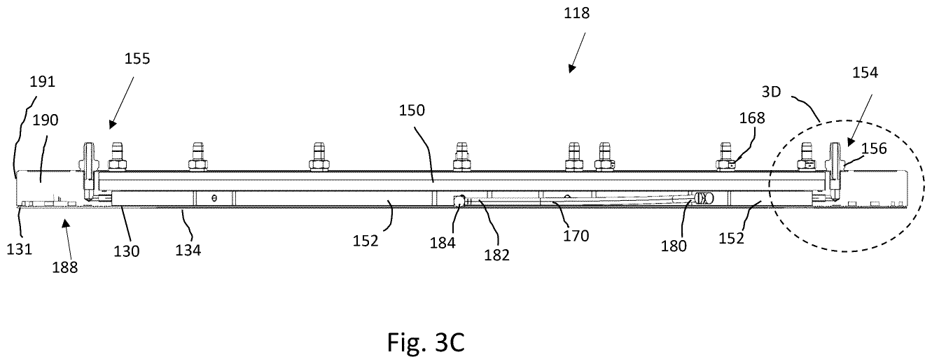

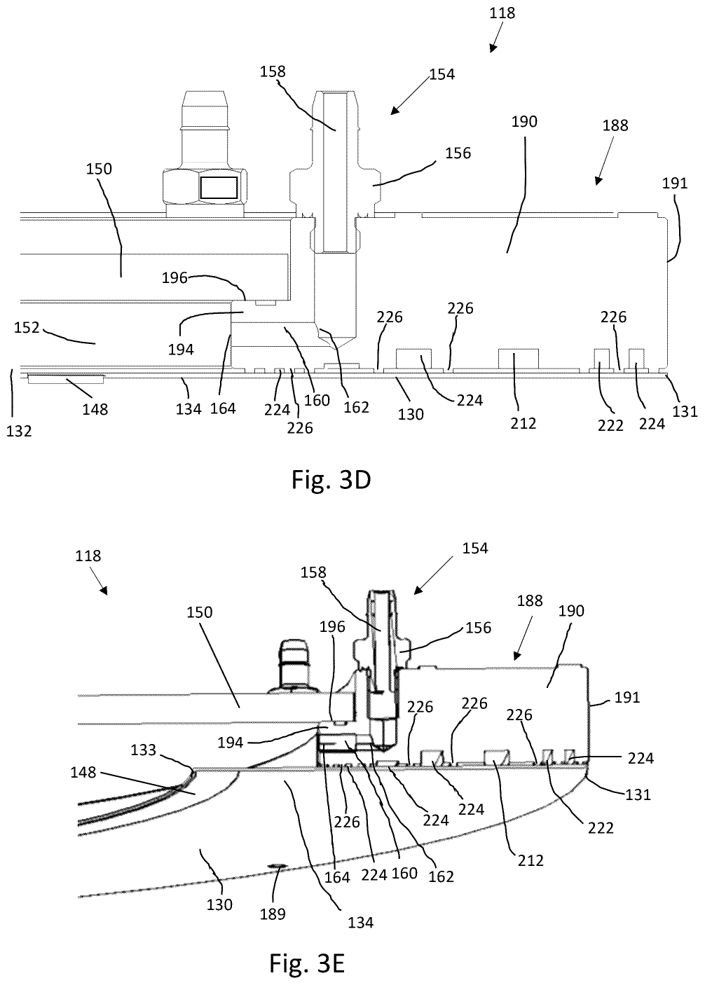

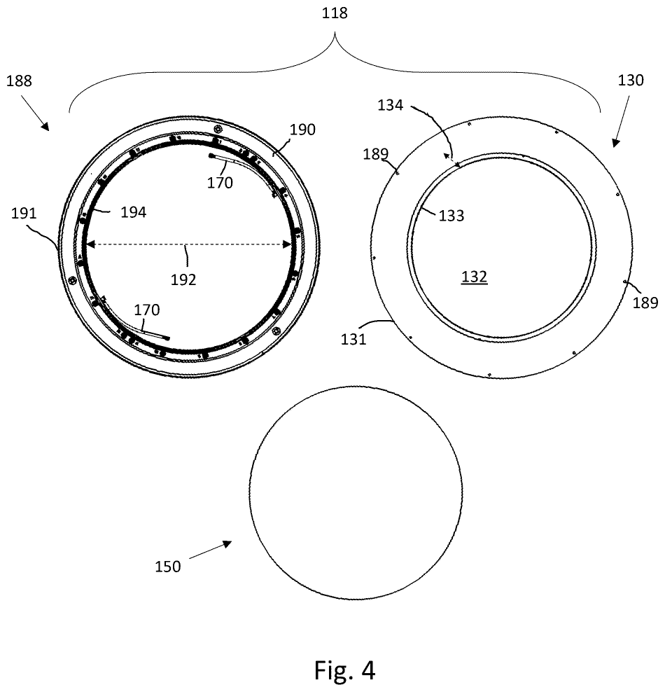

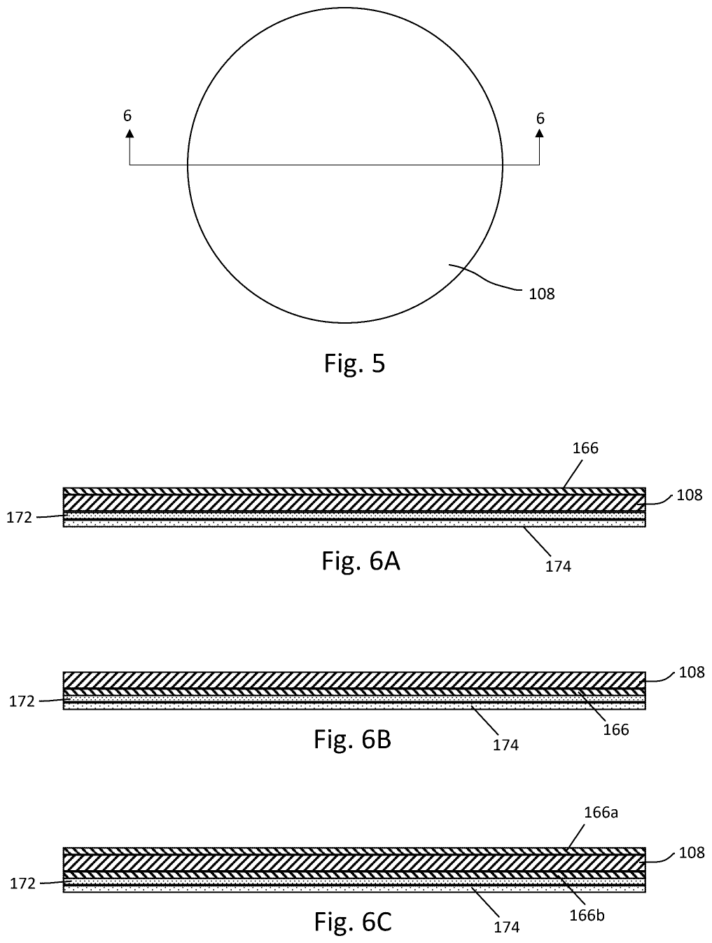

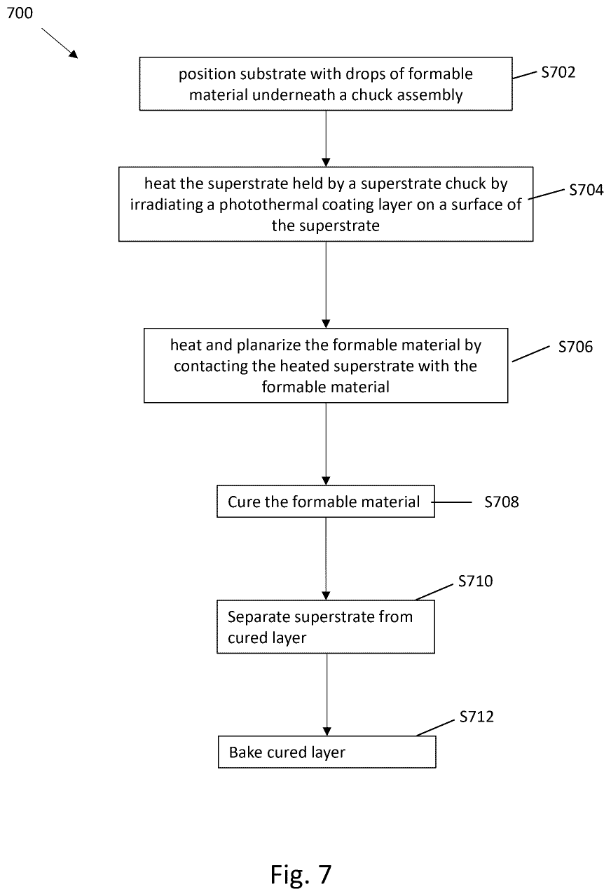

An example superstrate chuck assembly 118 is shown in FIGS. 3A to 4 in accordance with a first example embodiment. FIG. 3A shows a bottom view of the superstrate chuck assembly 118. FIG. 3B shows a top view of the superstrate chuck assembly 118. FIG. 3C shows a cross section taken along line 3C-3C of FIG. 3B. FIG. 3D shows an enlarged portion 3D of FIG. 3C. FIG. 3E shows a perspective view of the enlarged portion 3D of FIG. 3C.

As shown in FIGS. 3A to 3E, the superstrate chuck assembly 118 may include a superstrate holding member 130 preferably having a ring shape. The superstrate holding member 130 may include a flexible portion 134. The size of the flexible portion 134 of the superstrate holding member 130 may be varied while performing the planarization process, as discussed in U.S. Pat. No. 11,728,203, issued Aug. 15, 2023, which is hereby incorporated by reference herein in its entirety.

The superstrate holding member 130 may further include a cavity 148 (FIGS. 3D, 3E) configured to hold a portion of the superstrate 108 to the flexible portion 134 of the superstrate holding member 130. The cavity 148 may be an annular cavity concentrically surrounding the central opening 132. The cavity 148 may be located adjacent the inner edge 133 of the superstrate holding member 130. The cavity 148 may be formed as a recessed portion in the flexible portion 134.

The superstrate chuck assembly 118 may further include a light-transmitting member 150 that covers the central opening 132 of the superstrate holding member 130. In one example embodiment, the light-transmitting member 150 is preferably transparent to UV light with high UV light transmissivity. That is, the material composition of the light-transmitting 150 member may be selected such that UV light used to cure the formable material passes through the light-transmitting member 150. In one example embodiment when the light-transmitting member 150 transmits UV light, the light-transmitting member may be composed of a material that transmits greater than 80% of light having a wavelength of 310-700 nm (i.e., UV light and visible light), e.g., sapphire, fused silica). In another example embodiment, the light-transmitting member need not be transparent with respect to UV light. When the light-transmitting member need not be transparent with respect to UV light, the light-transmitting member may be composed of a material that transmits greater than 80% of light having a wavelength of 400-700 nm (i.e., visible light), e.g., glass, borosilicate. That is, in the case when it is not necessary to transmit UV light, the light-transmitting member 150 should still transmit visible light. The light-transmitting member 150 may be composed of a material that transmits greater than 50% of the wavelength of the light that the camera 136 uses to monitor the shape of the superstrate while the superstrate 108 is held by the superstrate chuck assembly 118 during the planarizing method.

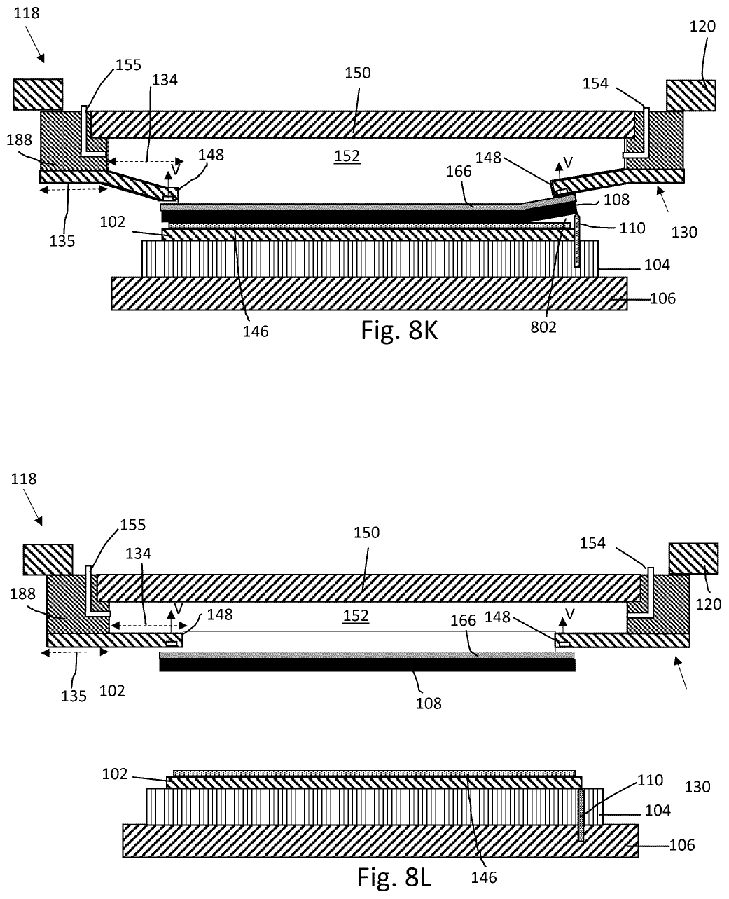

As best seen in FIGS. 3C, 3D, 3E, and FIGS. 8A to 8G, the superstrate chuck assembly 118 may include a chamber 152 defined by the superstrate holding member 130, the superstrate 108, and the light-transmitting member 150. More particularly, a bottom surface of the light-transmitting member 150, an upper surface and outer edge of the superstrate 108, and an upper surface of the superstrate holding member 130, being spaced apart, together define the chamber 152. The chamber 152 may be further defined by the inner side wall of a rigid member 188, discussed below. As also best seen in FIGS. 3C, 3D, 3E, the superstrate chuck assembly 118 may further include a fluid path 154 in communication with the chamber 152 for pressurizing the chamber 152. As used herein, pressurizing includes both positive pressure and negative pressure.

The fluid path 154 can also be used to open the chamber 152 to atmosphere. The fluid path 154 may include components that together allow the chamber 152 to be selectively positively or negatively pressurized. In the illustrated example, the fluid path 154 includes a first port 156 connectable with a pressurizing source (not shown). The introduction of gas, for example, from the pressure source into the chamber 152 pressurizes the chamber 152 when the superstrate 108 is held by the superstrate chuck assembly 118.

The first port 156 may be connected to the pressurizing source via a supply line. The first port 156 includes a first passage 158 in communication with the supply line and in communication with a second passage 160. A first end 162 of the second passage 160 connects with the first passage 158 and a second end 164 of the second passage 160 connects to the chamber 152. Thus, when the first port 156 is connected to the pressurizing source, positive pressure can be applied to pressurize the chamber 152 via the first fluid path 154. One or more additional fluid paths may be implemented that have the same structure as the above-discussed fluid path 154. For example, as best seen in FIG. 3C, an additional fluid path 155 having the same structure as the fluid path 154 may be located at a position diametrically opposing the fluid path 154. The additional fluid path 155 may serve as an outlet flow path for the pressurizing gas or may be a separate flow path used to further pressurize the chamber 152.

The superstrate 108 may be held by the flexible portion 134 by reducing pressure in the cavity 148. One manner of reducing pressure in the cavity 148 is providing a vacuum to the cavity 148. To provide a vacuum to the cavity 148 of the superstrate holding member 130, the superstrate chuck assembly 118 may further include a vacuum path in communication with the cavity 148. In a case that there is already a pressure differential within the assembly relative to the atmosphere around the assembly, the vacuum path can be used as a manner of reducing pressure in the cavity 148 without being coupled to a vacuum. The vacuum path may include components that together allow the cavity 148 to impart a vacuum onto the superstrate 108. The vacuum path includes a second port 168 connectable with a vacuum source (not shown) and a routing tube 170 connecting the second port 168 to the cavity 148. The second port 168 may be connected to the vacuum source via a vacuum supply tube (not shown), for example. The routing tube 170 may be a flexible tube having a first end 180 connected to the second port 168 and having a second end 182 connected to a fitting 184, e.g., a pneumatic fitting. The fitting 184 is also connected to a through hole formed through the flexible portion 134 of the superstrate holding member 130 and leading into the cavity 148. That is, by being connected to both the routing tube 170 and the through hole, the fitting 184 directs the vacuum suction downwardly into the cavity 148 via the through hole. Thus, when the second port 168 is connected to the vacuum source, a vacuum can be applied to cavity 148 in order to provide a suction force capable of coupling the area of the superstrate 108 under the cavity 148 with the flexible portion 134. Additional details for applying a vacuum to the cavity 148 can be found in U.S. Pat. No. 11,728,203.

One or more additional vacuum paths may be implemented that have the same structure as the above-discussed vacuum path, where each vacuum path is in communication with the same cavity 148 and/or communication with a corresponding additional cavity (not shown) formed in the superstrate holding member 130. The additional cavity or cavities may be disposed concentrically around the cavity 148. That is, the additional cavity or cavities may also be concentrically disposed around the central opening 132, but may be located at a greater radial distance from the inner edge 133 than the illustrated cavity 148. In an embodiment, the inner diameter of the superstrate holding member 130 may be smaller and/or the cavity 148 may have additional lands 226. For example, an additional vacuum path having the same structure as the above-described vacuum path may be located at a position diametrically opposing the above-described vacuum path. The additional cavity or vacuum cavities may be used to assist in separating the superstrate from a cured layer as part of the planarization process discussed below in more detail. In another aspect, the additional cavity or vacuum cavities allow the same superstrate chuck assembly 118 to be used with different sized superstrates.

In another embodiment, it is possible that the cavity 148 and vacuum path may be replaced with another mechanism for coupling the superstrate holding member 130 with a superstrate. For example, in place of a cavity/vacuum arrangement, an electrode that applies an electrostatic force may be included. Another option is mechanical latching where a mechanical structure on the underside of the superstrate holding member 130 is mateable (capable of making a good, close, and/or proper fit) with the superstrate.

The superstrate chuck assembly 118 may further include a rigid member 188. The rigid member 188 need not be made of a transparent material that allows for UV light to pass through. That is the rigid member 188 may be composed of an opaque material with respect to UV light. The rigid member 188 may be composed of plastic (e.g., acrylic), glass (e.g., fused silica, borosilicate), metal (e.g., aluminum, stainless steel), or ceramic (e.g., zirconia, sapphire, alumina). In an example embodiment, the rigid member 188 may be composed of the same material as the superstrate holding member 130.

FIG. 4 shows an exploded view where the rigid member 188 is shown separated from the superstrate holding member 130 and the light-transmitting member 150. As best seen in FIG. 4, the rigid member 188 may generally include a circular main body 190 defining an open central area 192. The outer circumference of the rigid member 188 may be uniform. The inner circumference of the rigid member 188 may include a step 194 that provides a receiving surface 196 for receiving the light-transmitting member 150. That is, as best seen in FIGS. 3D and 3E, the light-transmitting member 150 may be placed onto the receiving surface 196 of the step 194, thereby covering the central area 192. The light-transmitting member 150 may be secured onto the receiving surface 196, such as with an adhesive. In this manner, when the light-transmitting member 150 is placed/secured onto the receiving surface 196, the chamber 152 is defined by the underside surface of the light-transmitting member, the inner surface of rigid member 188 (more particularly, the inner surface of the step 194), the upper surface of the superstrate holding member 130, and the superstrate 108.

The superstrate holding member 130 may be coupled to the underside surface of the rigid member 188 using a coupling member (not shown) such as a screw, nut/bolt, adhesive, and the like. The coupling member may preferably be located adjacent to the outer edge 191 of the rigid member 188 and adjacent the outer edge 131 of the superstrate holding member 130. When the coupling member is a screw, the coupling member preferably passes through the superstrate holding member 130 adjacent the outer edge 131 and into the rigid member 188 adjacent the outer edge 191, such as through a plurality of receiving holes 189 (FIGS. 3E, 4). When the coupling member is an adhesive, the coupling member is preferably located between the superstrate holding member 130 adjacent the outer edge 131 and the rigid member 188 adjacent the outer edge 191. In this manner, an upper surface of the superstrate holding member 130 contacts and is fixed to the underside surface of the circular main body 190 of the rigid member 188 adjacent the outer edge 131 and the outer edge 191. Additional surface area of superstrate holding member 130 may be selectively coupled to the rigid member 188 as part of the planarization process. The manner of selectively coupling the additional surface area of the superstrate holding member 130 to the rigid member 188 is discussed in more detail below.

As shown in FIGS. 3C, 3D, and 3E, all or a portion of the fluid path 154 and/or additional fluid path 155 discussed above may be contained within the rigid member 188. Similarly, all or a portion of the vacuum path and/or additional vacuum path in communication with the cavity 148 may be contained within the rigid member 188. More particularly, a portion of the first port 156, a portion of the first passage 158, the second passage 160, the first end 162, and the second end 164 of the fluid path 154 may be contained within the rigid member 188. A portion of the second port 168, among other non-illustrated pathways, of the vacuum path may be contained within the rigid member 188. However, as best shown in FIGS. 3C and 4, the routing tube 170 may be external to the rigid member 188. Thus, the rigid member 188, in addition to supporting the light transmitting member 150 and the superstrate holding member 130, may also provide the pathway/structure for the fluid paths and vacuum paths. In an alternative embodiment, there is no routing tube 170 and the vacuum passes through a port in the rigid member 188 via a channel from the inflexible portion of the superstrate holding member 130 to the flexible portion 134 of the superstrate holding member 130 to the cavity 148.

The superstrate chuck assembly 118 may further include additional vacuum paths that allow the superstrate holding member 130 to be selectively secured to the underside surface of the rigid member 188. While the above-described vacuum flow paths communicate with the cavity 148 of the superstrate holding member 130, the additional vacuum paths that allow the superstrate holding member 130 to be selectively secured to the underside surface of the rigid member 188 are annular cavities in the rigid member 188 that are open on the underside surface of the rigid member 188. The details of these additional vacuum paths are described in U.S. Pat. No. 11,728,203. The additional vacuum paths may include components that together impart a vacuum suction force onto the upper surface of the superstrate holding member 130 to further secure the superstrate holding member 130 to the underside surface of the rigid member 188. The additional vacuum path may include a port 204 connectable with a vacuum source (not shown). The port 204 of the vacuum path may be connected to the vacuum source via a vacuum supply tube (not shown), for example. The port 204 of the vacuum path is in communication with an annular cavity 212 having an open end facing downwardly toward the superstrate holding member 130. Thus, when the port 204 of the vacuum path is connected to the vacuum source, and the upper surface of the superstrate holding member 130 is in contact with the underside surface of the rigid member 188, a vacuum can be applied to the annular cavity 212 to secure the superstrate holding member 130 to the rigid member 188. Further vacuum paths in communication with further annular cavities 222, and 224, each annular cavity having an open end facing downwardly toward the superstrate holding member 130. The further annular cavities may be spaced apart in a radial direction. Thus, a vacuum can be selectively applied to the annular cavities 212, 222, and 224. Details of selectively applying the vacuum to the annular cavities is provided in U.S. Pat. No. 11,728,203.

While the example embodiment of the superstrate chuck assembly 118 includes the rigid member 188 as a separate structural element from the superstrate holding member 130, in another example embodiment, the rigid member may be a single structural piece including a portion shaped like the flexible portion of the superstrate holding member and a portion shaped like the rigid member. In other words, in such an embodiment, there is no separate rigid member and instead there is a single continuous structure having a thick portion resembling the rigid member and thin portion resembling the flexible portion. Because there is not a separate rigid member ring and the superstrate holding member in such an embodiment, there is also no need for any of the annular cavities or a need for any of the ports and cavities that provide a vacuum path to the annular cavities. Rather, only the fluid path(s) and possibly vacuum path(s) leading to the chamber 152 (i.e., an equivalent to fluid path 154) and possibly the vacuum path(s) leading to the flexible portion of superstrate holding the member (i.e., an equivalent to vacuum path in communication with the cavity 148) would be present in this embodiment.

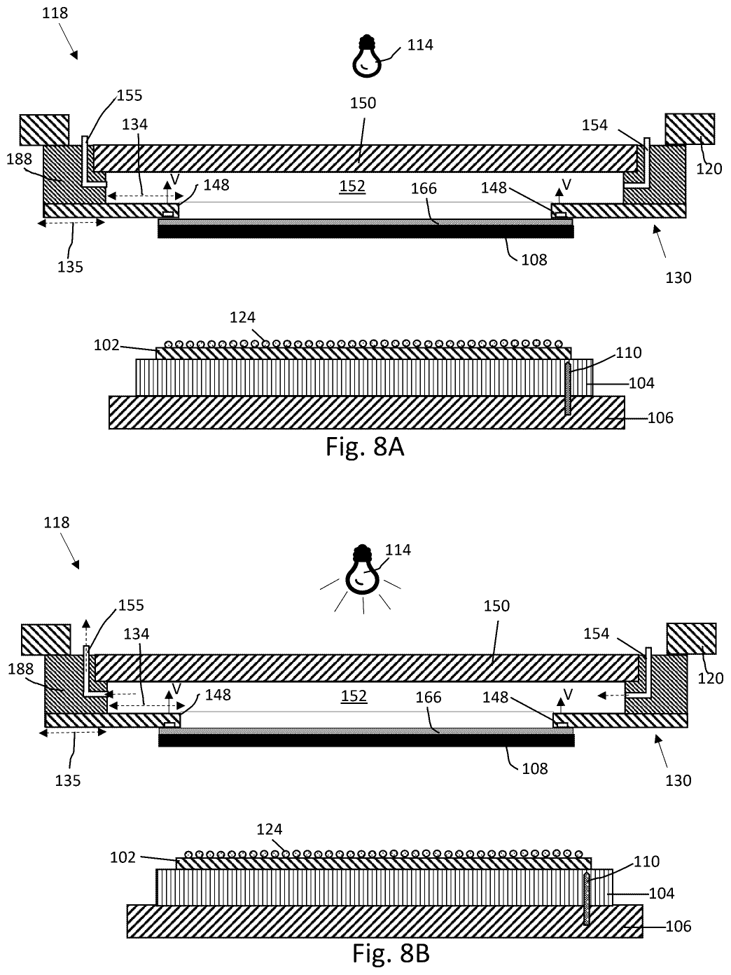

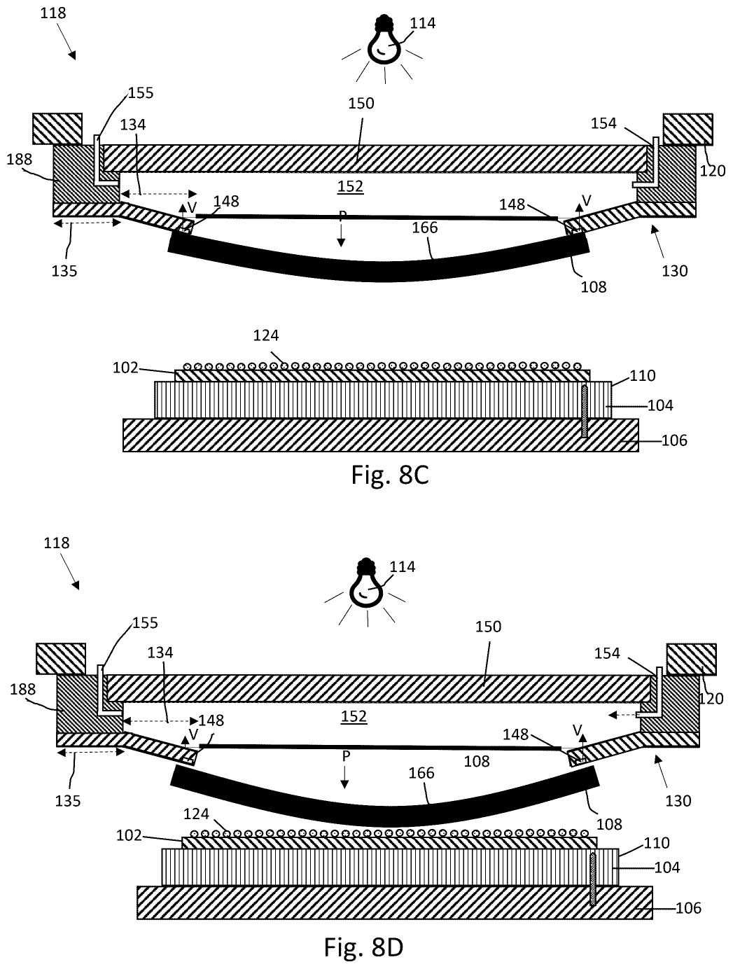

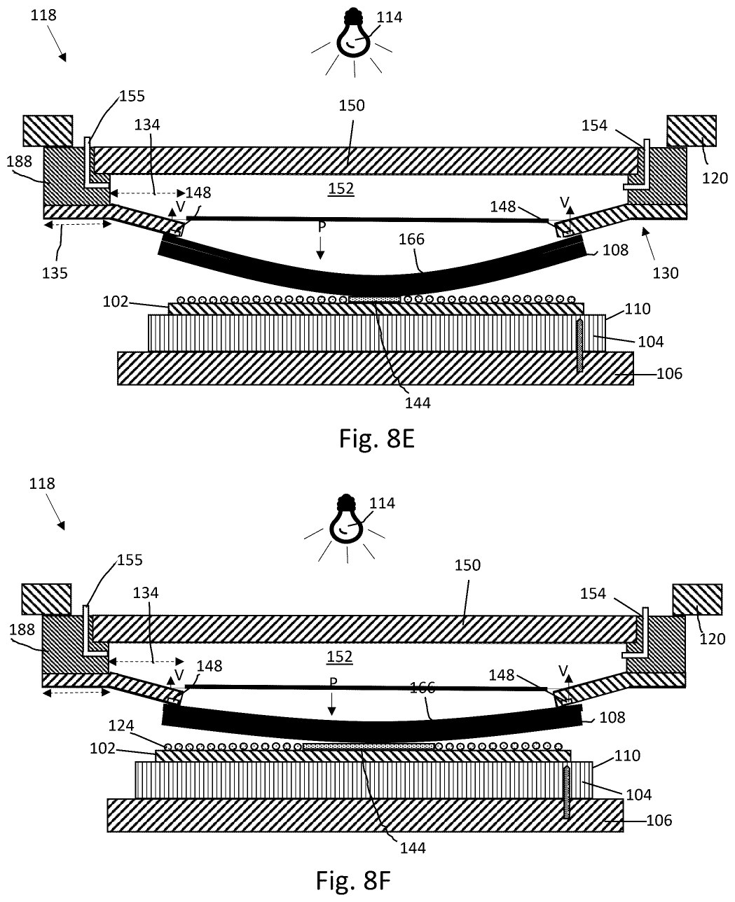

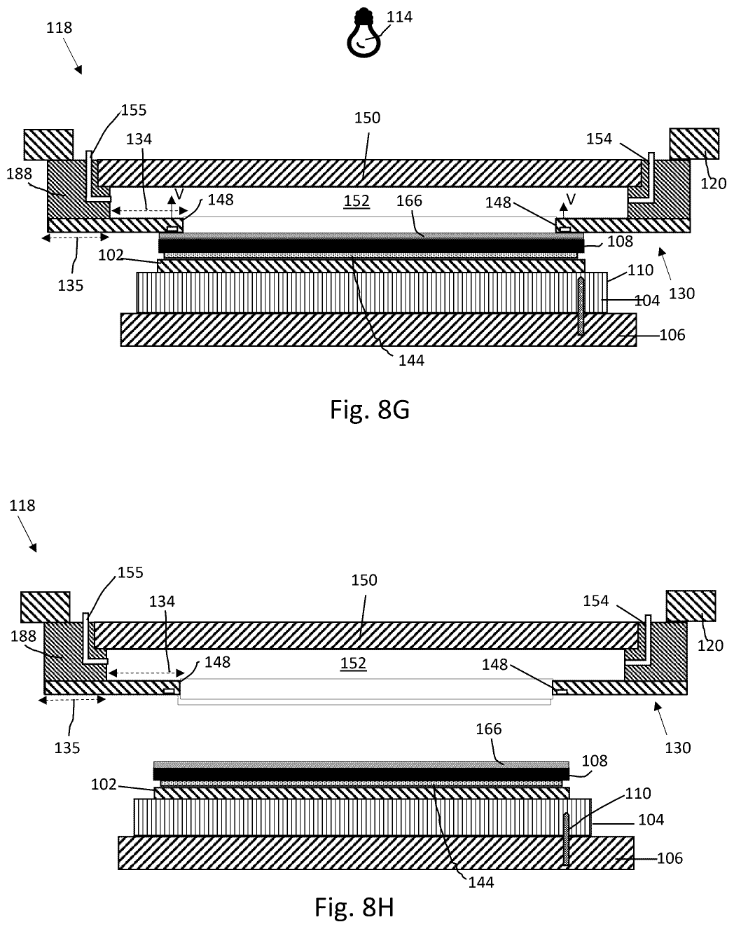

FIG. 5 shows a top schematic view of a superstrate 108. FIG. 6A shows a first example embodiment of a cross section of the superstrate 108 of FIG. 5 along line 6-6, in which a photothermal coating layer 166 is disposed on an upper surface of the superstrate 108. FIG. 6B shows a second example embodiment of a cross section of the superstrate 108 of FIG. 5 along line 6-6, in which a photothermal coating layer 166 is disposed on a bottom surface of the superstrate 108. FIG. 6C shows a third example embodiment of a cross section of the superstrate 108 of FIG. 5 along line 6-6, in which a photothermal coating layer 166a is disposed on a top surface of the superstrate 108 and a photothermal coating layer 166b is disposed on a bottom surface of the superstrate 108. As used herein, the top surface is the surface of the superstrate that faces the superstrate chuck assembly 118 and the bottom surface is the surface of the superstrate that faces the substrate 102.

The photothermal coating layers 166, 166a, and 166b are composed of a material that produces heat when irradiated with photothermal light. Different photothermal compositions have a peak absorbance of light at different light wavelengths. That is, certain photothermal compositions may absorb light across a spectrum of wavelengths which is then converted by the photothermal composition into heat, but there is a peak absorbance wavelength where absorption is maximized and the photothermal composition will produce maximum heat as compared to when being exposed to other light wavelengths. The photothermal coating layer preferably has a peak absorption wavelength that is different than the wavelength that will cause the formable material to cure. The formable material has a photoinitiator that also has a peak absorbance wavelength. When the photoinitiator is irradiated with light at/near the peak wavelength absorption, the formable material may at least partially cure. The photothermal coating layer 166 preferably has peak photothermal absorption wavelength that is outside a curing wavelength range of the formable material. The formable material includes a particular photoinitiator. Each photoinitiator will have an associated curing wavelength range in which actinic radiation induces a chemical change in the formable material causing the liquid formable material to polymerize, gel, and eventually solidify. Thus, if the photothermal coating layer is a photothermal composition that has a peak absorption wavelength that is the same or near to the wavelength that will cause the formable material to cure, irradiating the photothermal coating layer at the peak absorption wavelength will cause the formable material to prematurely cure. On the other hand, when the photothermal coating layer is a composition that has a peak absorbance wavelength different from the wavelength that causes the formable material to cure, irradiating the photothermal coating layer at the peak absorbance wavelength will allow the photothermal coating layer to produce heat without prematurely curing the formable material. In an example embodiment, the peak wavelength absorbance of the photothermal coating layer is greater than +/−5% of the wavelength that will cause the formable material to cure, more preferably +/−10%, more preferably +/−20%. The curing light wavelength is selected such that the light is absorbed by photoinitiator sufficient to initiate curing. In an example embodiment the wavelength that will cause the formable material to cure is 365 nm. Depending on the photoinitiator, the wavelength of the curing light may be 200 to 500 nm, preferably 300 to 400.

In an example embodiment, the peak absorbance wavelength of the photothermal coating layer is a wavelength other than 365 nm. In an example embodiment, the peak absorbance wavelength of the photothermal coating layer is 400 nm or higher, for example 400 nm to 2200 nm. Thus, in first radiation source 114 may be configured to emit light consistent with these wavelengths. For example, the first radiation source may be one or more LED(s) or laser(s) having a peak wavelength of for example 850 nm, 1.3 μm, or 1.55 μm. In an example embodiment, the photothermal coating is made of a material that has an absorbance at curing wavelengths of the curing light that is higher than an absorbance at photothermal wavelengths of the photothermal light. In which case the photothermal coating is thin enough (for example 1.55 μm) that it has high transmittance (greater than 90% or 97%) in the curing wavelength range and a photothermal absorbance in a photothermal range of 10-40%. The first radiation source 114 (photothermal radiation source) may supply 1 W/cm² for 10-60 seconds or 10-60 J/cm² of photothermal radiation in the photothermal wavelength range.

While the wavelength ranges provided above for the first radiation source and the second radiation source overlap, in any particular embodiment the wavelengths for each are preferably different. For example, if the first radiation source emits light having a wavelength of 400 nm (which appears in both ranges provided above) for a particular photothermal coating layer, then the second radiation source will emit light having a wavelength other than 400 nm for the particular photoinitiator. Thus, even though the above-listed wavelength ranges have some overlap, the light emitted from the first radiation source and the light emitted from the second radiation source preferably have different wavelengths.

In an aspect of the present disclosure, the photothermal coating layer 166, 166a, 166b may be composed of titanium dioxide, indium tin oxide, antimony tin oxide, for example. For example, a photothermal coating 166 have a thickness of 0.1 μm, a transmittance of at least 97% in a curing wavelength range and absorbance of at least 44% or at least 25% in a photothermal wavelength range.

In another aspect of the present disclosure, the photothermal coating layer 166, 166a, 166b may be composed of a plasmonic nanomaterial. The plasmonic nanomaterial is composed of nanoparticles having a size on the nanometer scale, i.e., in the range of 5 nm to 115 nm. Preferably, the nanoparticles of the plasmonic nanomaterial is 7 nm to 50 nm. The plasmonic nanoparticles may be dissolved in a solution including a matrix material and a solvent that may be applied to the surface of the superstrate by using spin coating. The matrix material may be a polymer material, a ceramic material, or a glassy material. The matrix material should be stable when exposed to light in the curing wavelength range and the photothermal range and be stable in the heating temperature range. The peak absorption wavelength of the plasmonic nanomaterial is determined by the size of the particles and the composition of the particles. The particle sizes and the composition may each be selected such that, in combination, the peak absorption wavelength is within the preferable ranges/values discussed above. The plasmonic nanomaterial may also comprise more than one composition as long as each composition and particle size for a particular composition has a similar peak absorption wavelength as the other compositions/particle sizes.

When the photothermal coating layer is a plasmonic nanomaterial, the plasmonic nanomaterial may be silver, gold, indium tin oxide, antimony tin oxide, titanium dioxide, doped cadmium oxide, oxygen deficient tungsten trioxide, doped zinc oxide, doped indium oxide, vacancy doped molybdenum dioxide or combinations thereof. When the plasmonic nanomaterial is silver, the particle size may be 10 nm to 40 nm, 30 to 40 nm, preferably 40 nm. When the plasmonic nanomaterial is made of gold spheres than the radius of the gold spheres may be 20-80 nm preferably 80 nm. When the plasmonic nanomaterial is made of silica particles encased in a 5-30 nm gold shell, then the silica particle size may be 40 nm to 120 nm, preferably 60 nm. When the plasmonic nanomaterial is made of gold nanorods with an aspect ratio of 3-4 having an effective radius of 3-30 nm, preferably 18 nm. The effective radius re of the nanorods is a function of the volume V of the nanorods

$$( {r}_{e} = \sqrt[3]{3 V / 4 π} ) .$$

When two photothermal coating layers 166a, and 166b are present (i.e., FIG. 6C), the photothermal coating layers 166a, 166b may be different or the same composition. When the two photothermal coating layers 166a, 166b are the same, the first radiation source 114 may emit a single wavelength range of light that corresponds to the peak absorbance wavelength of the composition of the photothermal coating layers such that the photothermal coating layers generate heat. When the two photothermal coating layers 166a, 166b are different, but have the same or approximately the same peak absorbance wavelength, the first radiation source 114 may similarly emit a single wavelength of light that corresponds to the peak absorbance wavelength of the two different photothermal coating layers such that the photothermal coating layers generate heat. When the two photothermal coating layers 166a, 166b are different, and have different peak absorbance wavelengths, the first radiation source 114 may be configured to emit different wavelengths of light that correspond to the peak absorbance wavelength of the respective photothermal coating layers such that the each of the photothermal coating layers independently generate heat. As noted above, each photothermal coating layer is selected such that the peak photothermal absorbance is different than the curing wavelength that causes curing of the formable material.

In another aspect of the present disclosure, there may be multiple photothermal coating layers stacked on top of one another. For example, for each individual photothermal coating layer 166, 166a, 166b shown in the figures, there may instead be two, three, four etc., photothermal coating layers layered on top of each other. In the case where there are multiple photothermal coating layers on top of another, the multiple photothermal coating layers may be the same or different and may have the same or different peak absorbance wavelengths. As above, when the multiple photothermal coating layers are the same, the first radiation source 114 may emit light at a single wavelength and when the multiple photothermal coating layers are different the first radiation source 114 may emit additional light spanning multiple different wavelengths that correspond to the different peak absorbance wavelengths of the photothermal coating layers.

As shown in FIGS. 6A to 6C, additional layers 172, 174 may be present on the bottom side of the superstrate 108 so that superstrate does not directly contact the formable material on the substrate during planarizing. The additional layers 172, 174 may be a gas absorption layer 172, for example polymethyl methacrylate (PMMA) and a release layer 174. The release layer 174 has a lower adhesion force than the gas absorption material when they are in contact with the formable material. One possible release layer 174 is CYPTOP™ from AGC, Inc. of Tokyo Japan. As shown in FIGS. 6A to 6C, the release layer 174 may be the outermost layer that comes into contact with the formable material during planarizing, while the gas absorption layer 172 may be on the other side of the release layer 174. As shown in FIGS. 6B and 6C, in the case that there is a photothermal coating layer 166, 166b on the bottom side of the superstrate, the photothermal coating layer 166, 166b contacts the superstrate, the gas absorption layer 172 contacts the photothermal coating layer 166, 166b, and the release layer 174 contacts the gas absorption layer 172. That is, in all of the embodiments shown in FIGS. 6A to 6C, the bottommost two layers are the gas absorption layer 172 and the release layer 174. Therefore, even when the photothermal coating layer is on the bottom side of the superstrate, the photothermal coating layer does not come into contact with the formable material during planarizing. The gas absorption layer 172 is a layer that absorbs gas underneath the superstrate during the planarizing method 700. In an alternative embodiment, the gas absorption layer and the gas release layer are combined into a single layer. In another alternative embodiment, the plasmonic nanoparticles are dispersed into the gas absorption layer so that the gas absorption layer also acts as a photothermal layer. The matrix material of the plasmonic nanomaterials may be the material of the gas absorption layer 172. In an embodiment, a superstrate 108 has one or more photothermal layers 166. In an embodiment, a superstrate 108 has a gas absorption layer 172 and one or more photothermal layers 166. In an embodiment, a superstrate 108 has one or more photothermal layers 166 that also acts as gas absorption layer. In an embodiment, a superstrate 108 has a gas absorption layer that has plasmonic nanoparticles embedded in it.

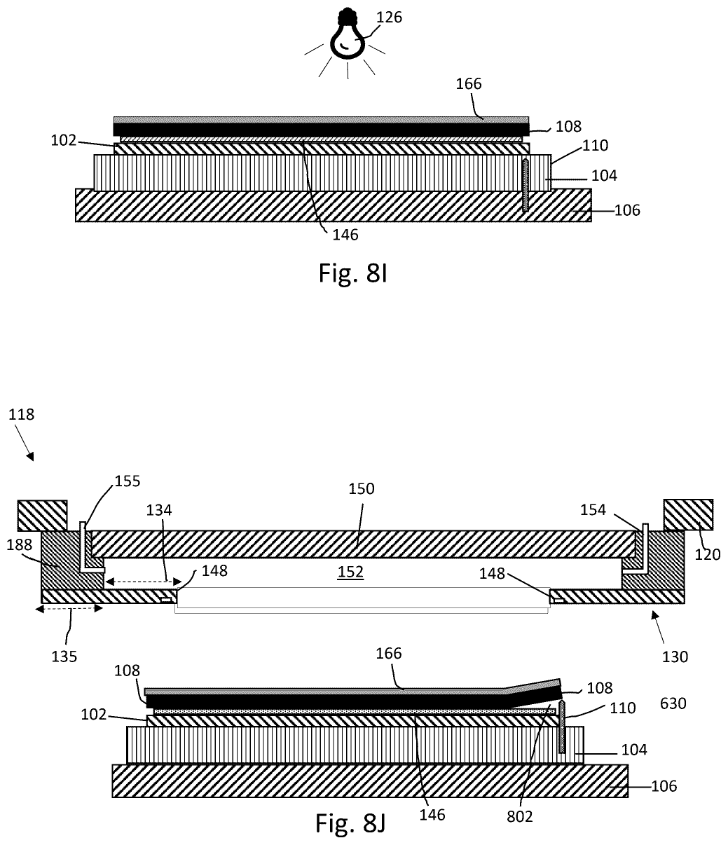

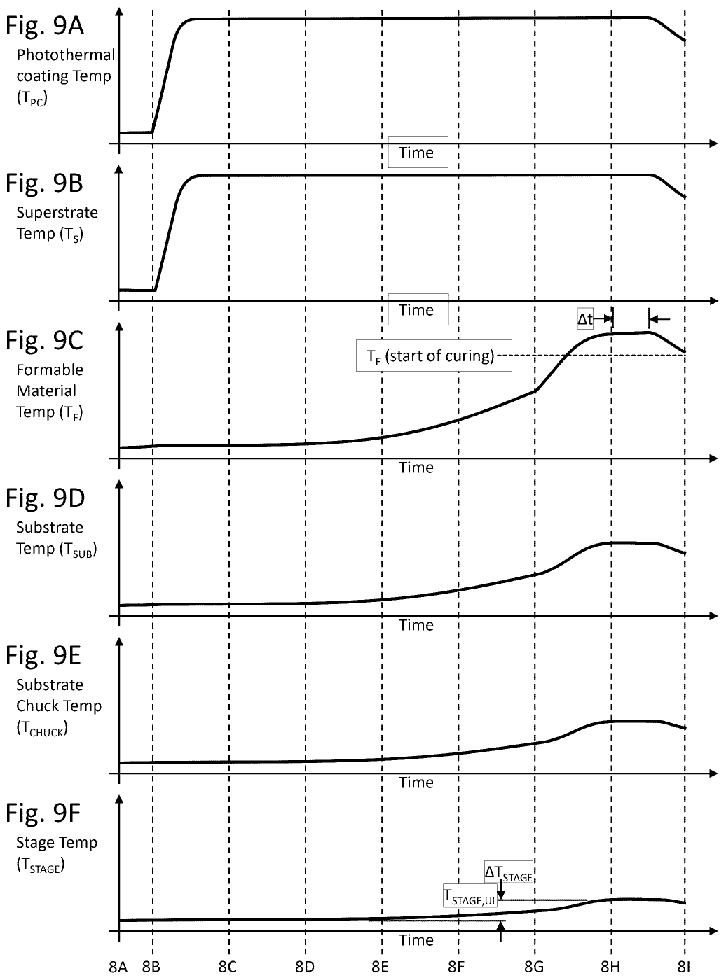

Operation of the superstrate chuck assembly 118 as part of the planarizing process will now be described with reference to FIGS. 7-8L. FIG. 7 shows a flow chart of a planarizing method 700. FIGS. 8A to 8L show cross sectional schematic views of the planarizing method 700 using the superstrate chuck assembly 118 and in which the photothermal coating layer 166 is on a surface of the superstrate 108. As shown in FIG. 8A to 8L, in the illustrated embodiment, the photothermal coating layer 166 is disposed on the top surface of the superstrate 108 and the additional layers 172, 174 are omitted for simplicity. However, the processes illustrated in FIGS. 8A to 8L are applicable to all the embodiments shown in FIG. 6A to 6C, and to non-illustrated embodiments such as when there are multiple photothermal coating layers stacked on top of each other. Furthermore, for simplicity, the schematic representation of FIGS. 8A to 8L have omitted the cavities 212, 222, 224, among other features. FIGS. 9A to 9G are timing charts indicating the temperature of various components of the planarization system 100 at different times in the planarizing method 700.

The method begins at step S702, where the substrate 102 having drops of formable material 124 dispensed thereon, is brought underneath the superstrate 108 that is coupled with the superstrate holding member 130 of the superstrate chuck assembly 118. Thus, prior to performing step S702, the drops of formable material are dispensed onto the substrate in the manner described above. This moment is shown in FIG. 8A. FIG. 8A shows a schematic cross section of the substrate 102 having dispensed formable material 124 positioned below the superstrate 108 being held by the superstrate chuck assembly 118.

Prior to performing step S702, the superstrate chuck assembly 118 is prepared by applying the vacuum suction to the cavity 148 of the superstrate holding member 130 and contacting the cavity 148 to the upper side surface of the superstrate 108, thereby coupling the superstrate 108 to the superstrate holding member 130. In a case where there are multiple vacuum cavities (e.g., 2) in the flexible portion 134 of the superstrate holding member 130, in one embodiment, less than all (e.g., only one) of the vacuum cavities will have a vacuum implemented during step S702. For example, in one embodiment, only the radially outermost cavity relative to the central opening 132 may have a vacuum imparted. However, in another embodiment, all of the vacuum cavities (e.g., 2) may have a vacuum implemented during step S702.

As shown in FIG. 8A, at the time that the substrate 102 is placed underneath the superstrate 108, the chamber 152 may not yet be pressurized with positive pressure and the first radiation source 114 has not yet been activated so that the photothermal coating layer 166 has not yet begun to generate heat. In another embodiment, to improve throughput, the chamber 152 may be preemptively pressurized with positive pressure prior to the substrate 102 being positioned underneath the superstrate 108. Furthermore, during a calibration step prior to the moment shown in FIG. 8A, negative pressure may be applied in the chamber 152. At the moment shown in FIG. 8A, the pressure P in the chamber is preferably equal to the ambient pressure, e.g., atmospheric pressure, but may also be positively pressurized or negatively pressurized. The moment shown in FIG. 8A also serves at the starting, or zero point, with respect to time on the timing charts of FIGS. 9A to 9F. Each of the timing charts in FIGS. 9A to 9F show the temperature of a different aspect of the planarization system 100 over the same period. That is, the same point of the x-axis across all of the timing charts indicates the corresponding temperature of each of the components at that same moment.

FIG. 9A is a timing chart of the temperature T_{PC} of the photothermal coating layer 166. The temperature discussed herein with respect to the temperature of the photothermal coating layer 166 is the average temperature across the volume of the photothermal coating layer 166. FIG. 9B is a timing chart of the temperature T_{S} of the superstrate 108. The temperature discussed herein with respect to the temperature of the superstrate 108 is the average temperature across volume of the superstrate 108. FIG. 9C is a timing chart of the temperature T_{F} of the formable material (formable material droplets 124 and formable material film 144). The temperature discussed herein with respect to the temperature of the formable material 124 and the formable material film 144 is the average temperature across the volume of the formable material. FIG. 9D is the is a timing chart of the temperature T_{SUB} of substrate 102. The temperature discussed herein with respect to the temperature of the substrate 102 is the average across the volume of the substrate. FIG. 9E is the is a timing chart of the temperature T_{CHUCK} of substrate chuck 104. The temperature discussed herein with respect to the temperature of the substrate chuck 104 is the average across the volume of the substrate chuck. FIG. 9F is the is a timing chart of the temperature T_{STAGE} of substrate positioning stage 106. The temperature discussed herein with respect to the temperature of the substrate positioning stage 106 is the highest measured temperature, at a particular time, measured across the entire volume of the substrate positioning stage 106. In other words, different portions of the substrate positioning stage 106 may have different temperatures at a particular time. The temperature T_{STAGE} is the temperature of the portion having the highest measured temperature.

FIGS. 9B to 9F reflect that each of these components begin at a similar starting temperature prior to irradiating the photothermal coating layer 166 with photothermal light emitted by the first radiation source 114.

The method may then proceed to step S704, where the superstrate 108 is heated by irradiating the photothermal coating layer 166 on the surface of the superstrate 108 using the first radiation source 114. Step S704 may include several sub-steps. FIG. 8B shows a schematic cross section of the superstrate chuck assembly during a first sub-step when the first radiation source 114 has been activated to emit light toward the photothermal coating layer 166. As discussed above, the first radiation source 114 is configured to emit light have a wavelength that is in the peak absorbance wavelength range of the photothermal coating layer, which causes the photothermal coating layer 166 to generate heat. At the same time, the pressure within the chamber 152 is maintained low enough that the superstrate 108 is not bowed.

FIG. 8C shows a schematic cross section of the superstrate chuck assembly 118 after the moment shown in FIG. 8B, during a second sub-step when pressure has built up in the chamber 152 sufficient to bow the superstrate 108. In the moment shown in FIG. 8C, the first radiation source 114 has continued to emit light toward the photothermal coating layer 166. At the same time, the pressure in the chamber 152 is increased by introducing a pressurizing gas into the chamber via one or more of the fluid paths 154, 155. The increase in pressure in the chamber 152 causes the superstrate 108 to bow. At the same time the superstrate 108 may move down toward the formable material 124 on the substrate 102 and/or the substrate 102 carrying the formable material 124 may be brought up toward the superstrate 108. During this time, the superstrate 108 continues to be further bowed as pressure continues to build in the chamber 152 and the superstrate 108 continues to be heated by the irradiated photothermal coating layer 166.

The timing charts in FIGS. 9A to 9F show any changes in temperature that occur during the time between the moment shown in FIG. 8B, when the first radiation source 114 emits light toward the photothermal coating layer 166, to the moment shown in FIG. 8C, after the superstrate 108 has been heated and bowed.

As shown in FIG. 9A, the photothermal coating layer 166 becomes hotter as the photothermal coating layer 166 absorbs light emitted by the first radiation source 114. As shown in FIG. 9B, the temperature T_{S} of the superstrate 108 begins to increase as the photothermal coating layer 166 generates heat, and continues to increase throughout the time to reach the moment in FIG. 8C. In an example embodiment, the superstrate temperature T_{S} may increase by 0% to 204% from the moment of FIG. 8B to the moment in FIG. 8C, the temperature T_{S} may increase by 0° C. to 47° C. from the moment of FIG. 8B to the moment in FIG. 8C, and the superstrate temperature T_{S} may be 23° C. to 70° C. at the moment in FIG. 8C.

As shown in FIGS. 9C-9F, the formable material temperature T_{F} of the formable material 124 substrate temperature T_{SUB}, the substrate chuck temperature T_{CHUCK}, and substrate positioning stage temperature T_{STAGE}, will begin to slightly increase after the superstrate temperature T_{S} begins to increase after the temperature of superstrate 108 begins to increase. This is because superstrate 108 gets hotter, and the proximity of the superstrate 108 gets closer to the formable material 124, heat will begin to transfer to the formable material 124, but relatively slowly until contact is initiated.

FIG. 8D shows a schematic cross section of the superstrate chuck assembly 118 during a third sub-step when the pressure has further built up in the chamber 152 sufficient to further bow the superstrate 108 as compared to the moment shown in FIG. 8C. That is, the pressure in the chamber 152 at the moment shown in FIG. 8D is greater than the pressure in the chamber 152 as the moment shown in FIG. 8C. Furthermore, the superstrate 108 is more significantly bowed at the moment shown in FIG. 8D as compared to the moment shown in FIG. 8C. The pressure in the chamber 152 at the moment shown in FIG. 8D may be greater than the pressure in the chamber 152 at the moment shown in FIG. 8C. In the moment shown in FIG. 8D, the chamber 152 has continued to be pressurized via the pressurizing source. The increase in pressure in the chamber 152 causes the superstrate 108 to bow further. At the moment shown in FIG. 8D, the superstrate 108 has moved down toward the formable material 124 on the substrate 102 and/or the substrate 102 carrying the formable material 124 has been brought up toward the superstrate 108 such that the superstrate 108 is nearly touching the formable material. During this time, the superstrate 108 continues to be further bowed as pressure continues to build in the chamber 152 and the superstrate 108 and continues to be heated by the photothermal coating layer 166 as the first radiations source 114 continues to emit light onto the photothermal coating layer 166. That is, as shown in FIGS. 9A to 9F, the temperature of all of the above-mentioned components continue to increase but only slightly.

The method may then proceed to step S706 where the formable material 124 is heated and planarized by contacting the formable material with the heated superstrate 108. The step S706 is shown in FIGS. 8E to 8G. FIG. 8E shows a schematic cross section of the superstrate chuck assembly 118 at the moment the heated bowed superstrate 108 has come into contact with the formable material 124 beginning to form a formable material film 144. As shown in FIG. 8E, the chamber 152 remains pressurized. The vacuum suction continues to be applied to the cavity 148. In an embodiment, the pressure P in the chamber 152 is increased as the superstrate 108 conforms with the formable material 124 to maintain a desired curvature. The applicant has determined that it often requires more pressure to maintain a certain superstrate curvature as the un-conformed region of the superstrate decreases. As a contact area of the superstrate increases during step S706 the contact area of the superstrate begins to conform to the shape of the substrate under the contact area, while the portion of the superstrate outside the contact area is the un-conformed region in which the curvature needs to be controlled. Maintaining this curvature is important for minimizing gas trapping which can lead to non-fill defects. In an embodiment, the curvature just beyond the conformed portion (contact area) of the superstrate is controlled. In other words, the curvature of the superstrate in an annular region just outside the contact area is controlled. In an embodiment, a desired superstrate curvature profile in this annular region is controlled while formable material spreads underneath the contact area. This may require that the pressure P be maintained and/or increased during step S706. In an embodiment, the superstrate 108 is ‘flat’ (conforms to the shape of the substrate 102) after the formable material 124 has stopped spreading.

As the heated superstrate 108 comes into contact with the formable material, in addition to being planarized to form the formable material film 144, heat is further transferred from the superstrate 108 to the formable material film 144. That is, because the superstrate 108 has been heated via the photothermal coating layer 166 being exposed to light from the first radiation source 114, and because the formable material 124 is at a lower temperature prior to step S706, at the time of the contact of the superstrate 108 with the formable material 124 at the moment shown in FIG. 8E will continue to cause the formable material 124 to heat as it is simultaneously planarized into the formable material film 144. More specifically, the superstrate 108 will continue to transfer heat to the formable material 124, among the other components.

FIG. 8F shows a schematic cross section of the superstrate chuck assembly 118 as it continues to move downwardly toward the substrate 102 to further form the formable material film 144. During this time the heated superstrate 108 continues to heat and planarize the formable material 124 into formable material film 144. As seen in FIG. 8F, as the superstrate 108 continues to press downwardly, the formable material film 144 of formable material 124 spreads further along the surface of the substrate 102 toward the edges. The positive pressure P is further increased or maintained so as to maintain the desired curvature in the area of the substrate that is about to conform with the formable material. As the superstrate 108 continues to press downwardly toward the substrate 102, the superstrate 108 continues to bend to maintain the desired curvature in the area of the substrate that is about to conform with the formable material. Thus, the superstrate 108 in FIG. 8F has less of an arc than in FIG. 8E such that the area of the superstrate 108 that is about to conform with the formable material maintains the desired curvature. At the same time, the flexible portion 134 also begins to flatten. The vacuum suction is still applied to the cavity 148 in FIG. 8F.

As the heated superstrate 108 further comes into contact with the formable material 124, in addition to being further planarized into the formable material film 144, further heat is transferred from the superstrate 108 to the formable material film 144, and the other components mentioned above.

In an example embodiment, the first radiation source 114 is driven to supply radiation to the photothermal coating layers 166 so that a target temperature, a target temperature range or a target temperature trajectory of the formable material is maintained during steps S704 and S706 until the start of step S708. A sensed temperature of the photothermal coating layer 166, the superstrate 108, or the formal material film 144 may be detected and used in feedback or feedforward to control the first radiation source 114. The first radiation source 114 may be a constant or pulsed source of photothermal radiation during steps S704 and S706.

FIG. 8G shows a schematic cross section of the superstrate chuck assembly 118 at a point where the superstrate 108 has been fully pressed against the formable material 124 such that the formable material film 144 is fully formed. As shown in FIG. 8G, the superstrate 108 has been pressed until it is once again flat. That is, the superstrate 108 no longer has an arc or lacks a substantial arc. Similarly, the flexible portion 134 of the superstrate holding member 130 is flat or lacks a substantial bend. As shown in FIG. 8G, emission of light from the first radiation source 114 may have been terminated at this time. That is, the photothermal coating layer 166 is no longer being irradiated. In an alternative embodiment, the emission of light from the first radiation source continues until the start of step S708. The vacuum suction is still applied to the cavity 148. With superstrate 108 fully contacting the formable material film 144, in addition to having fully planarized the formable material 124 into the formable material film 144, the formable material film 144 has been heated.

In an example embodiment, heat is transferred from the superstrate 108 to the formable material film 144, and onward to the substrate 102, the substrate chuck 104 and the substrate positioning stage 106. The first radiation source 114 can compensate for this loss of heat by continually exposing the photothermal coating layer 166 to photothermal radiation until, the superstrate is no longer underneath the first radiation source.

The photothermal coating layer 166, 166a, 166b may be selected such that, when irradiated for 10-60 seconds and approximately 1 W/cm², a temperature change of the photothermal coating layer 166, 166a, 166b from prior to irradiating (i.e., prior to the moment of FIG. 8B) until the start of curing (i.e., the moment of FIG. 8I) is 20% to 220%. The photothermal coating layer 166, 166a, 166b may be selected such that, when irradiated for 10-60 seconds and approximately 1 W/cm², a temperature change of the photothermal coating layer 166, 166a, 166b from prior to irradiating until terminating the irradiation is 5° C. to 50° C. higher. The photothermal coating layer 166, 166a, 166b may be selected such that, when the irradiation is terminated after 10-60 seconds and approximately 1 W/cm², the temperature of the photothermal coating layer 166, 166a, 166b is 5° C. to 50° C. The photothermal coating layer 166, 166a, 166b may be selected such that the temperature of the photothermal coating layer 166, 166a when the radiation is terminated after 10-60 seconds and approximately 1 W/cm² is 20% to 220% greater than the temperature of the formable material prior to contacting the superstrate with the formable material.

The photothermal coating layer 166, 166a, 166b may be selected such that, when irradiated for 10-60 seconds and approximately 1 W/cm², a temperature change of the formable material from prior to contacting the superstrate (i.e., prior to the moment of FIG. 8E) until the start of curing (i.e., the moment of FIG. 8I) is 20% to 220% higher. The photothermal coating layer 166, 166a, 166b may be selected such that, when irradiated for 10-60 seconds and approximately 1 W/cm², a temperature change of the formable material from prior to contacting the superstrate until the start of curing is 5° C. to 50° C. higher. The photothermal coating layer 166, 166a, 166b may be selected such that, when irradiated for 10-60 seconds and approximately 1 W/cm², a temperature of the formable material upon the start of curing is 5° C. to 50° C.

The method may then proceed to step S708, where the formable material film 144 located between the superstrate 108 and the substrate 102 is cured to create a planarized layer. FIG. 8H shows a schematic cross section of the superstrate chuck assembly 118 when the superstrate 108 is first released from the superstrate holding member 130. To release the superstrate 108 the vacuum applied to the cavity 148 is terminated. More particularly, because the superstrate 108 is contacting the formable material film 144, the termination of the vacuum to the cavity 148 releases a multilayer structure comprising the superstrate 108, the formable material film 144, and the substrate 102. The multilayer structure is supported by the substrate chuck 104.

As shown in FIGS. 9A-B as soon as photothermal coating layer 166 is no longer irradiated (i.e., at the moment shown in FIG. 8G), the temperatures T_{PC} of the photothermal coating layer 166 and T_{S} of the superstrate 108 begins to drop. That is, after reaching peak temperature, with the first radiation source 114 no longer emitting light, the heat in the system begins to dissipate. As seen in FIGS. 9C to 9F, each of the other components also have a temperature drop after the irradiation is terminated. However, the components that are farther away from the photothermal coating layer take longer for the heat to begin to dissipate and the temperature to reduce. That is, the temperature T_{S} of the superstrate 108 begins to decrease after the temperature T_{PC} of the photothermal coating layer 166 begins to decrease, the temperature T_{F} of the formable material film 144 begins to decrease after the temperature T_{S} of the superstrate 108 begins to decrease, the temperature T_{SUB} of the substrate 102 begins to decrease after the temperature T_{F} of the formable material film 144 begins to decrease, the temperature T_{CHUCK} of the substrate chuck 104 begins to decrease after the temperature T_{SUB} begins to decrease, and the temperature T_{STAGE} of the substrate positioning stage 106 begins to decrease after the temperature T_{CHUCK} of the substrate chuck 104 begins to decrease.

At the moment shown in FIG. 8H, where the superstrate 108/formable material film 144/substrate 102 has been released from the superstrate holding member 130, the temperature of all of the components continues to decrease. This continued decrease in temperature is illustrated in FIGS. 9B to 9F. As shown in FIGS. 9B to 9F, the temperature of each of the components continues to decrease after the moment shown in FIG. 8H and the formable material temperature is at a target curing temperature T_{F}(start of curing) at the moment shown in step 8I (start of curing step S7080).

Importantly, the highest temperature of the substrate positioning stage 106 stays below an upper limit temperature (T_{stage,UL}) that may be for example 27° C. throughout the entire process. In addition, of the substrate positioning stage temperature may stay within a substrate positioning stage temperature range (ΔT_{STAGE}) of about 5° C. That is, the peak temperature T_{STAGE} that is shown in FIG. 9F occurring between the moment of FIG. 8G and the moment of FIG. 8H, is below 27° C. if the ambient temperature is 23° C. Staying below this temperature prevents variation in the planarization performance. Other approaches for heating the formable material, such as heating the substrate with a heated substrate chuck, may cause the stage to increase in temperature by more than 5° C. In an embodiment, a processor 140 will determine photothermal radiation parameters based on the desired formable material temperature T_{F} at the start of curing. The desired formable material temperature T_{F} at the start of curing may be determined based on a baking temperature during the baking step S712. The photothermal radiation parameters may include one or more of: photothermal radiation wavelength(s); photothermal radiation exposure time(s); photothermal exposure intensity(ies); photothermal exposure power(s); the photothermal exposure dose(s); a superstrate with a particular photothermal coating; photothermal exposure intensity trajectory; photothermal exposure power trajectory; photothermal exposure dose trajectory. The processor 140 may select the photothermal radiation parameters such that the formable material film 144 is within a critical range (for example ±0.1° C., ±0.5° C., ±1° C., ±2° C., or ±5° C.) of the desired formable material temperature T_{F} at the start of curing while also minimizing a variation in substrate positioning stage temperature range (ΔT_{STAGE}). One method of minimizing a variation in substrate positioning stage temperature range (ΔT_{STAGE}) is to minimize a period of time Δt that the formable material film is at a maximum temperature. Another method may include minimizing the total photothermal energy supplied by the first radiation source 114. The processor 140 may select the photothermal radiation parameters such that the formable material film 144 is within a critical range (for example ±0.1° C., ±0.5° C., ±1° C., ±2° C., or ±5° C.) of the desired formable material temperature T_{F} at the start of curing while also ensuring that a variation in substrate positioning stage temperature range (ΔT_{STAGE}) is less than a target variation in substrate positioning stage temperature range (ΔT_{STAGE}) for example 0.2° C., 1° C., 2° C., or 5° C.). The selection method may include simulating the thermal transfer of the heat using finite element methods or other simulation techniques and/or experimental methods of measuring different temperatures of the formable material film 144 and the substrate positioning stage 106. The planarization system 100 may also include an active cooling system in the substrate chuck 104 or the substrate positioning stage 106 that keeps the substrate positioning stage temperature within a narrow range. The substrate chuck 104 may include a reflective coating that reflects light at one or both the curing wavelength and the photothermal wavelength.

After the superstrate 108 has been released from the superstrate holding member 130 and a after a static spread period, the superstrate 108/formable material film 144/substrate 102/substrate chuck 104 may be moved via the substrate positioning stage 106 to another location for curing (step S708) using the curing system. As shown in FIG. 8I, once the combination of superstrate 108/formable material film 144/substrate 102/substrate chuck 104 is present at the other location, the curing process can be performed. The curing may be performed by exposing the formable material film 144 to actinic radiation (for example UV light) through the superstrate 108 using the second radiation source 126. However, because the combination of superstrate 108/formable material film 144/substrate 102/substrate chuck 104 is at another location and no longer coupled to the superstrate chuck assembly 118, the UV light does not need to pass through the light-transmitting member 150 or through the superstrate holding member 130. In this embodiment, where the UV radiation does not pass through the light-transmitting member, the light-transmitting member 150 may be composed of a material that transmits greater than 80% of light having a wavelength of 400-700 nm (i.e., visible light and not UV light), e.g., glass, borosilicate, and does not need to be composed of a material that transmits UV light. After the curing is complete, the combination of superstrate 108/planarized layer 146/substrate 102/substrate chuck 104 may be brought back underneath the superstrate chuck assembly 118. After exposure to the UV radiation, the formable material film 144 of formable material is cured, thereby forming a hardened cured planarized layer 146.

As noted above, FIG. 9B to 9F show the temperature of each of the components varying throughout planarization process until the moment of curing shown in FIG. 8I. Importantly, at the start of curing, the temperature of the formable material film 144 has reached a predetermined temperature that has been determined is ideal for the start of curing. The predetermined temperature for curing the formable material is a temperature that avoids the issues noted above, i.e., non-uniform topography is avoided or minimized in the surface of the baked layer when the temperature of the formable material is at the predetermined temperature at the time of curing which is determined based on the baking temperature. The predetermined temperature of the formable material at the start of curing may be between 25° C. to 80° C., 40° C. to 70° C., or 50° C. to 60° C. depending on the formable material and the baking temperature during step S712. The photothermal coating layer, the photothermal radiation wavelength, the photothermal radiation exposure time, and the photothermal exposure intensity (or power or dose) is selected by taking into account the time and dissipation of heat from the formable material film 144 that occurs during the period from when the exposure to photothermal radiation from the first radiation source 114 stops to the moment that the formable material is cured. In other words, the composition of the photothermal coating layer, the photothermal radiation wavelength, the photothermal radiation exposure time, and/or the photothermal exposure intensity (or power or dose) is selected such that the temperature of the formable material film 144 will increase to a temporary higher temperature and then the temperature of the formable material film 144 will naturally decrease on the way to curing to ultimately arrive at the ideal curing temperature. This ideal curing temperature may be 20% to 220% greater than the baseline temperature (ambient temperature for example 23° C.) of the formable material prior to any heating. The photothermal coating layer 166, 166a, 166b may be selected such that, after irradiating for 10-60 seconds with 1 W/cm², a temperature change of the formable material 124 from prior to contacting the superstrate (i.e., prior to the moment of FIG. 8E) until the start of curing (i.e., the moment of FIG. 8I) is 20 to 220% higher. The photothermal coating layer 166, 166a, 166b may be selected such that, after irradiating for 10-60 seconds with 1 W/cm², a temperature change of the formable material from prior to contacting the superstrate until the start of being cured is 25° C. to 80° C. higher. The photothermal coating layer 166 may be selected such that, after irradiating for 10-60 seconds with 1 W/cm², a temperature of the formable material film 144 at the start of curing is 50° C. to 60° C.

In another embodiment, the curing step may be performed after the combination of superstrate 108/planarized layer 146/substrate 102/substrate chuck 104 is released from the superstrate holding member, but without moving the combination of superstrate 108/planarized layer 146/substrate 102/substrate chuck 104 to another location. That is, the curing can occur at the same location as the superstrate chuck assembly 118, but with the combination of superstrate 108/planarized layer 146/substrate 102/substrate chuck 104 at a distance below the superstrate chuck assembly 118. In this case, the second radiation source 126 may emit, for example, UV radiation that is directed through the light-transmitting member 150 and through the superstrate 108, each of which allow the UV radiation to pass through. In an embodiment the superstrate holding member 130 may be transparent to the actinic radiation (for example UV radiation). In the embodiment where the UV radiation passes through the light-transmitting member, the light-transmitting member 150 may be composed of a material that transmits greater than 80% of light having a wavelength of 310-700 nm (i.e., UV light and visible light), e.g., sapphire, fused silica). In which case the photothermal coating layer 166 can be exposed to photothermal radiation right up to the moment that curing starts and the formable material will not significantly cool down prior to the start of curing.

In the case where the curing occurs at the same location as the chuck assembly, the temperatures of the photothermal coating layer, superstrate, substrate, formable material, etc. at the time of curing is the same as provided above when the curing occurs at a separate curing location. However, because there is less time for heat to dissipate after the formable material is planarized into the formable material film 144, the temperature of the photothermal coating layer after being irradiated may be lower than the case where the curing happens at the same location. For example, after irradiating, the photothermal coating layer 166 may have a temperature that is 5% lower when the curing occurs at the same location compared to when the curing occurs at a different location.

The method may then proceed to step S710, where the superstrate 108 is separated from the planarized layer 146. FIG. 8J shows a schematic cross section of the superstrate chuck assembly 118 above the combination of superstrate 108/planarized layer 146/substrate 102, at a moment when a separation initiator 110 has been extended upwardly to initiate a separation front between the superstrate 108 and the planarized layer 146. The substrate chuck 104 may include the separation initiator 110. The separation initiator 110 may be a pushpin in one example embodiment. The separation initiator 110 may reside within a passageway extending through the substrate chuck 104. The separation initiator 110 is configured to move upwardly. The separation initiator 110 may extended through a hole or notch in the substrate 102 and contact the underside of the superstrate 108. As shown in FIG. 8J the separation initiator 110 may come into contact with the underside of the superstrate 108 at the outer edge of the superstrate 108. The application of upward force on the underside of the superstrate 108 by the separation initiator causes a small portion of the superstrate 108 to release form the planarized layer 146. This initial separation at the edge is also an initiation of a separation front between the superstrate 108 and the planarized layer 146.

Next, with the separation front having been initiated, the superstrate 108 may be recoupled with the superstrate holding member 130. FIG. 8K shows schematic cross section of the superstrate chuck assembly 118 and the combination of superstrate 108/planarized layer 146/substrate 102, at a moment when the superstrate 108 has been recoupled with the superstrate holding member 130. As shown in FIG. 8K, the vacuum is once again applied to the cavity 148 so that the upper surface of the superstrate 108 is coupled with the superstrate holding member 130. After the superstrate 108 is once again coupled with the superstrate holding member 130, the separation front may be propagated until compete separation of the superstrate 108 form the planarized layer 146 is achieved. The separation front may be propagated through lifting and/or rotating the superstrate chuck assembly 118 until the complete separation is achieved. A detailed method of separating the superstrate 108 from the planarized layer 146 is described in U.S. Pat. App. Pub. No. US 2023/0095200, published Mar. 30, 2023, which is hereby incorporated by reference it its entirety.

FIG. 8L shows a moment once the separation of step S710 has been competed just after superstrate 108 has been released from the planarized layer 146. As shown in FIG. 8L after completing the separation, the superstrate chuck assembly 118 retains the superstrate 108 and the substrate 102 retains the planarized layer 146. The planarization method 700 can be then be started again for another substrate by returning to the orientation shown in FIG. 8A. As noted above, the planarization method 700 may be repeated many times, on the order of tens of thousands. When it is desirable to remove the superstrate 108 from the superstrate chuck assembly 118 (for example after a predetermined number of planarization processes have been completed or if some other indicator suggests that the superstrate should be replaced), the vacuum applied to the vacuum cavity 148 may be released.

After the superstrate 108 is removed from the cured planarized layer 146, the substrate 102 with a cured planarized layer 146 is removed from the substrate chuck 104. The substrate 102 with the cured planarized layer 146 may then be baked during a baking step S712. The baking step S712 may be performed in a baking module that is a part of the planarization system 100 or in a separate baking tool. The baking step S712 is performed at a baking temperature and a baking soak time. The baking temperature in step S712 may be selected based on subsequent processing steps. The baking step S712 will have a tendency to increase the degree of polymerization of the cured planarized layer. The baking steps S712 can also have an impact on the planarization performance as the baked layer shrinks relative to the cured planarized layer 146. The applicant has found that the planarization performance after baking can be improved if the temperature at the start of curing is selected based on the baking temperature. The applicant has found that it is helpful to store a cure temperature-baking temperature look up table that includes a relationship between the baking temperature and the curing temperature of the formable material at the start of curing. This look up table may be generated based on experimental performance in which a variety of films are formed and baked at different temperatures. This look up table may then be used to select the photothermal coating and/or the photothermal radiation wavelength, the photothermal dosage, the photothermal intensity, the photothermal radiation duration or photothermal radiation trajectory supplied by the first radiation source. The processor 140 may receive the planned baking temperature and send instructions to the first radiation source based on the cure temperature-baking temperature look up table. The processor 140 may receive the planned baking temperature and send instructions to load a particular superstrate with a particular photothermal coating.

Embodiments as described herein can be used to keep a thickness change between a baked layer and a pre-cured layer or between a baked layer and a cured layer of a photocurable composition closer to 0% when comparing photocuring temperature at higher than ambient temperature as compared to photocuring at ambient temperature. A moderate photocuring temperature, as compared to too low or too high of a photocuring temperature, may allow a thickness change of 0% to be achieved. Better dimensional stability helps to make processes more robust and repeatable from substrate to substrate and from production lot to production lot. The inventors have found that for each material there is photocure thickness change that is dependent upon the photocuring temperature and there is baking thickness change that is dependent upon the baking temperature. The inventors have found that it is possible to select that one of the photocure thickness change and baking thickness change is positive while the other is negative so as to give an optimal thickness change as close to zero as possible.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description.

What is claimed is:

1. A planarizing method, comprising:
heating a superstrate held by a superstrate chuck by irradiating a photothermal coating layer on a surface of the superstrate; and
heating and planarizing a formable material by contacting the heated superstrate with the formable material.

2. The method of claim 1, wherein the surface is a top surface of the superstrate or a bottom surface of the superstrate.

3. The method of claim 2, wherein the superstrate further includes:
a gas absorption layer; and
a release layer that is disposed on the gas absorption layer,
wherein the contacting of the heated superstrate with the formable material comprise contacting the release layer with the formable material.

4. The method of claim 3,
wherein the gas absorption layer is the photothermal layer and includes plasmonic nanoparticles with a peak photothermal absorption wavelength that is outside a curing wavelength range of the formable material.

5. The method of claim 1,
wherein the surface is a top surface of the superstrate,
wherein a second photothermal coating layer is disposed on a bottom surface of the superstrate; and
wherein the photothermal coating layer on the top surface of the superstrate has a different composition than the second photothermal coating layer on the bottom surface of the superstrate.

6. The method of claim 1,
wherein the surface is a top surface of the superstrate,
wherein a second photothermal coating layer is disposed on a bottom surface of the superstrate; and
wherein the photothermal coating layer on the top surface of the superstrate has the same composition as the second photothermal coating layer on the bottom surface of the superstrate.

7. The method of claim 1, wherein the photothermal coating layer has a peak absorbance wavelength that is different than a wavelength that cures the formable material.

8. The method of claim 1, wherein the photothermal coating layer has a peak absorbance wavelength that is other than 365 nm.

9. The method of claim 1, wherein the photothermal coating layer has a peak absorbance wavelength that is 400 nm or higher.

10. The method of claim 1, wherein the photothermal coating layer is composed of a member selected from the group consisting of titanium dioxide, indium tin oxide, and antimony tin oxide and combinations thereof.

11. The method of claim 1, wherein the photothermal coating layer is composed of a plasmonic nanomaterial comprising nanoparticles.

12. The method of claim 11, wherein a composition of the nanoparticles and a size of the nanoparticles are selected such that the plasmonic nanomaterial has a peak absorbance wavelength that is different than a wavelength that cures the formable material.

13. The method of claim 11, wherein the nanoparticles are composed of a member selected from the group consisting of silver, gold, indium tin oxide, antimony tin oxide, titanium dioxide, doped cadmium oxide, oxygen deficient tungsten trioxide, doped zinc oxide, doped indium oxide, vacancy doped molybdenum dioxide, and combinations thereof.

14. The method of claim 11, wherein the nanoparticles are silver and have a particle size of 5 to 10 nm.

15. The method of claim 1, wherein the irradiating comprises irradiating the photothermal coating layer such that a temperature change of the formable material from prior to contacting the superstrate until the formable material has completely spread is 20 to 220%.

16. The method of claim 1, further comprising
curing the formable material after the formable material has completely spread,
wherein the photothermal coating layer is selected such that, after the irradiating, the temperature of the spread formable material is 28° C. to 73° C. at the start of the curing.

17. The method of claim 1, further comprising:
curing the formable material after the formable material has completely spread to form a cured material; and
baking the cured material at a predetermined baking temperature,
wherein the irradiating is performed for a period of time based on the predetermined baking temperature.

18. The method of claim 1,
wherein the formable material is on a substrate carried by a stage, and
wherein a temperature of the stage is less than 28° C. when the formable material is heated and planarized.

19. A planarization system, comprising:
a superstrate;
a superstrate chuck configured to hold the superstrate;
a photothermal coating layer on a surface of the superstrate; and
a light source configured to emit light to irradiate the photothermal coating layer such that the photothermal coating layer generates heat.

20. A method of manufacturing an article, comprising:
dispensing a formable material on a substrate;
heating the superstrate held by a superstrate chuck by irradiating a photothermal coating layer on a surface of the superstrate;
heating and planarizing the formable material by contacting the heated superstrate with the formable material;
curing the formable material;
separating the superstrate from the cured formable material;
baking the cured formable material at a baking temperature, wherein photothermal radiation parameters for irradiating the photothermal coating are determined based on the baking temperature; and
processing the baked formable material to make the article.
